(19) United States
(12) Patent Application Publication
(10) Pub. No.: US 2026/0123340 A1
(43) Pub. Date: Apr. 30, 2026

(54) APPARATUS FOR TRANSFERRING SUBSTRATE

(71) Applicant: Samsung Display Co., LTD., Yongin-si (KR)

(72) Inventors: KWANGBOK PARK, Yongin-si (KR); TAEKYUN NA, Yongin-si (KR); SANGHYUN MOON, Yongin-si (KR); JAE IK BAE, Yongin-si (KR); YOUNG BOK YOON, Yongin-si (KR); HEUNGWON LEE, Yongin-si (KR); SUNTAEK HONG, Yongin-si (KR)

(21) Appl. No.: 19/210,749

(22) Filed: May 16, 2025

(30) Foreign Application Priority Data
Oct. 31, 2024 (KR) 10-2024-0152896

(51) Int. Cl. H01L 21/677

(52) U.S. Cl. CPC H10P 72/3202; H10P 72/3216

(57) ABSTRACT

An apparatus for transferring a substrate includes: loading plate, a substrate loading part disposed on the loading plate, a rail disposed below the loading plate and extending in a first direction, a driving part disposed in an accommodation space defined within the rail, and connected to the loading plate through an opening defined in an upper portion of the rail, and wheels connected to both opposing sides of the driving part in a second direction that intersects perpendicular to the first direction. Each of the wheels includes a first wheel core, a second wheel core surrounding a first outer circumferential surface of the first wheel core when viewed in the second direction, and fan blades disposed between the first wheel core and the second wheel core. When viewed in the first direction, the fan blades are disposed to be inclined at a first angle with respect to the second direction.

This application claims priority to Korean Patent Application No. 10-2024-0152896, filed on Oct. 31, 2024, and all the benefits accruing therefrom under 35 U.S.C. § 119, the content of which in its entirety is herein incorporated by reference.

### BACKGROUND

The present disclosure herein relates to an apparatus for transferring a substrate.

In general, display devices feature display panels including a plurality of pixels for generating images. The display panels are manufactured through a plurality of process chambers. Each pixel includes a transistor disposed on a substrate and a light-emitting element disposed on the transistor and connected to the transistor. The transistor and the light-emitting element of the pixel are manufactured in the process chambers.

During the manufacture of the display panel, the substrate is transferred to the process chamber, in which a predetermined device is provided on the substrate. Afterward, the substrate is transferred to the next process chamber for subsequent processes. A vehicle is used to transfer the substrate. The vehicle moves along a rail to transfer the substrate to the process chambers.

When the vehicle moves along the rail, friction generated between the vehicle and the rail produces particles. These particles may contaminate the substrate, creating a need for the development of technologies to effectively remove the particles.

### SUMMARY

The present disclosure provides an apparatus for transferring a substrate, capable of easily removing particles that may cause contamination.

An embodiment of the invention provides an apparatus for transferring a substrate, the apparatus including: a loading plate; an inner substrate loading part disposed on the loading plate; a rail disposed below the loading plate and extending in a first direction; a driving part disposed in an accommodation space defined within the rail, and connected to the loading plate through an opening defined in an upper portion of the rail; and a plurality of inner wheels connected to both opposing sides of the driving part in a second direction that intersects perpendicular to the first direction, where each of the inner wheels includes: a first wheel core; a second wheel core surrounding a first outer circumferential surface of the first wheel core when viewed in the second direction; and a plurality of fan blades disposed between the first wheel core and the second wheel core, and, when viewed in the first direction, the fan blades are disposed to be inclined at a first angle with respect to the second direction.

In an embodiment of the invention, an apparatus for transferring a substrate includes: a loading plate; a substrate loading part disposed on the loading plate; a driving part disposed below the loading plate; and a plurality of wheels connected to both opposing sides of the driving part in a first direction, where each of the wheels includes: a first wheel core; a second wheel core surrounding an outer circumferential surface of the first wheel core; and a plurality of fan blades disposed between the first wheel core and the second wheel core. Each of the wheels includes an inner surface facing the driving part and an outer surface opposite to the inner side surface, each of the fan blades includes a first side adjacent to the inner surface of each of the wheel and a second side adjacent to the outer surface of each of the wheel, and the first side of the fan blade and the second side of the fan blade are disposed at different heights when viewed in a second direction perpendicular to the first direction.

In an embodiment of the invention, an apparatus for transferring a substrate includes: a loading plate; a substrate loading part disposed on the loading plate; a driving part disposed below the loading plate; and a plurality of wheels connected to both opposing sides of the driving part in a certain direction. Each of the wheels includes: a first wheel core; a second wheel core surrounding an outer circumferential surface of the first wheel core; and a plurality of fan blades disposed between the first wheel core and the second wheel core, each of the wheels includes an inner surface facing the driving part and an outer surface opposite to the inner side surface, each of the fan blades includes a first side adjacent to the inner surface of each of the wheels and a second side adjacent to the outer surface of each of the wheels, a reference line extending from the second side of each of the fan blades in the certain direction is defined, and each of the fan blades is disposed to be inclined at an acute angle with respect to the reference line.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a block diagram of a panel manufacturing plant including an apparatus for transferring a substrate according to an embodiment of the invention;

FIG. 2 is a view of a plurality of vehicles and a rail disposed within a booth shown in FIG. 1;

FIG. 3 is a view illustrating an example of a planar configuration of a substrate to be loaded onto the vehicles shown in FIGS. 1 to 6;

FIG. 4 is a view illustrating an example of a display panel manufactured with pixels disposed on each unit substrate shown in FIG. 3;

FIG. 5 is a view illustrating an example of a cross-section of a pixel shown in FIG. 4;

FIG. 6 is a view illustrating a cross-section taken along line I-I′ shown in FIG. 2;

FIG. 7 is a view separately illustrating a driving part and wheels disposed within the rail shown in FIG. 6;

FIG. 8 is a view illustrating a more detailed configuration of an inner substrate loading part shown in FIG. 6;

FIG. 9 is a top view illustrating a mother substrate disposed in loading spaces shown in FIG. 8;

FIG. 10 is a front view illustrating the vehicle and rail shown in FIG. 6, as seen from a front defined by a traveling direction;

FIG. 11 is a view illustrating a detailed configuration of a pair of wheels disposed in a second direction, selected from wheels shown in FIG. 7;

FIG. 12 is a view illustrating the wheels shown in FIG. 11, with a second wheel core removed and a first wheel core and fan blades separately illustrated;

FIG. 13 is a front view illustrating one of the fan blades shown in FIG. 12;

FIG. 14 is a view illustrating the first wheel core and the fan blades shown in FIG. 12, as viewed from the second direction, with the outer surface of the first wheel core visible;

FIG. 15 is a perspective view of comparative wheels according to a comparative embodiment;

FIG. 16 is a cross-sectional view of two adjacent holes in one of the comparative wheels shown in FIG. 15;

FIG. 17 is an enlarged view illustrating the vehicle and rail shown in FIG. 10;

FIG. 18 is a view illustrating a comparative vehicle and rail including comparative wheels according to a comparative embodiment;

FIG. 19 is a view illustrating simulation results of airflow generated by the wheels according to various embodiments of the invention and by the comparative wheels shown in FIG. 15;

FIG. 20 is a view illustrating a configuration of fan blades according to another embodiment of invention;

FIG. 21 is a view illustrating a configuration of wheels according to another embodiment of the invention;

FIG. 22 is a view illustrating a configuration of one of outer substrate loading parts shown in FIG. 1;

FIG. 23 is a perspective view illustrating a substrate transfer part shown in FIG. 22;

FIG. 24 is a cross-sectional view taken along line II-II′ of FIG. 23; and

FIGS. 25A to 25D are views illustrating the operation of one of robot arms disposed within a main body shown in FIGS. 22 and 23.

### DETAILED DESCRIPTION

In this specification, it will also be understood that when one component (or region, layer, portion) is referred to as being “on”, “connected to”, or “coupled to” another component, it can be directly disposed/connected/coupled on/to the one component, or an intervening third component may also be present.

Like numbers refer to like elements throughout. Also, in the figures, the thickness, ratio, and dimensions of components are exaggerated for clarity of illustration.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” The term “and/or” includes any and all combinations of one or more of the associated listed items.

Although the terms “first,” “second,” etc. may be used herein to describe various elements, these elements should not be limited by these terms. The terms are used solely for the purpose of distinguishing one component from another. For example, a first element referred to as a first element in an embodiment can be referred to as a second element in another embodiment without departing from the scope of the appended claims. The singular forms include the plural forms as well, unless the context clearly indicates otherwise.

Also, “under”, “below”, “above’, “upper”, and the like are used for explaining relation association of components illustrated in the drawings. The terms may be a relative concept and described based on directions expressed in the drawings.

Unless otherwise defined, all terms (including technical and scientific terms) used herein have the same meaning as commonly understood by a person of ordinary skill in the art to which this invention belongs. In addition, terms such as those defined in commonly used dictionaries should be interpreted as having meanings consistent with their meanings in the context of the relevant technology, and unless explicitly defined, it should not be interpreted in an overly idealistic or overly formal sense.

It will be understood that the term “include” or “comprise”, when used in this specification, specifies the presence of stated features, integers, steps, operations, elements, components, or a combination thereof, but does not preclude the presence or addition of one or more other features, integers, steps, operations, elements, components, or combinations thereof.

Hereinafter, embodiments of the invention are described with reference to the drawings.

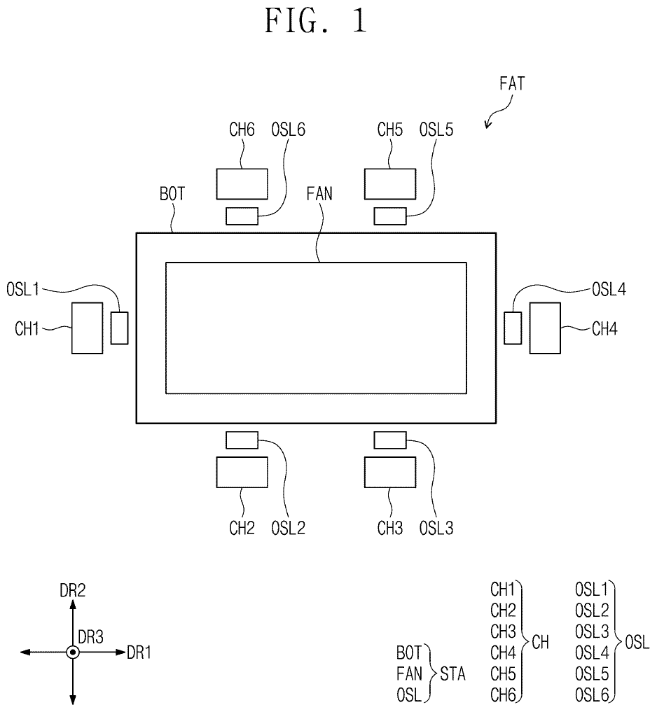

FIG. 1 is a block diagram of a panel manufacturing plant including an apparatus for transferring a substrate (hereinafter, referred to as a “substrate transfer apparatus”) according to an embodiment of the invention.

As an example, FIG. 1 is illustrated as a plan view.

Referring to FIG. 1, a panel manufacturing plant FAT may include a plurality of process chambers CH and a substrate transfer apparatus STA. The process chambers CH may be disposed adjacent to the substrate transfer apparatus STA. The process chambers CH may be disposed so as to surround the substrate transfer apparatus STA.

As an example, six process chambers CH are illustrated, but the number of process chambers CH is not limited thereto. The process chambers CH may include first to sixth process chambers CH1 to CH6.

The substrate transfer apparatus STA may include a booth BOT, a blower FAN, and a plurality of outer substrate loading parts OSL. The booth BOT may have long sides extending parallel to a first direction DR1 and short sides extending parallel to a second direction DR2, which intersects the first direction DR1. Thus, the booth BOT may extend longer in the first direction DR1 than in the second direction DR2.

Hereinafter, a direction that intersects substantially perpendicular to a plane defined by the first direction DR1 and the second direction DR2 may be defined as a third direction DR3. Also, in this description, the expression “a plan view” may mean a state when viewed in the third direction DR3.

The blower FAN may be disposed on the booth BOT. The blower FAN may include a plurality of fans (not shown) to blow air toward the booth BOT, thereby forming an airflow inside the booth BOT.

The outer substrate loading parts OSL may be disposed to surround the booth BOT. The outer substrate loading parts OSL may be disposed between the process chambers CH and the booth BOT. As an example, six outer substrates loading parts OSL are illustrated, but the number of outer substrate loading parts OSL is not limited thereto.

The outer substrate loading parts OSL may include first to sixth outer substrate loading parts OSL1 to OSL6. The first to sixth outer substrate loading parts OSL1 to OSL6 may be disposed adjacent to the first to sixth process chambers CH1 to CH6, respectively.

The first to sixth outer substrate loading parts OSL1 to OSL6 may allow substrates, which are processed in the first to sixth process chambers CH1 to CH6, to be loaded thereon, or substrates, which are transferred within the booth BOT, to be loaded thereon.

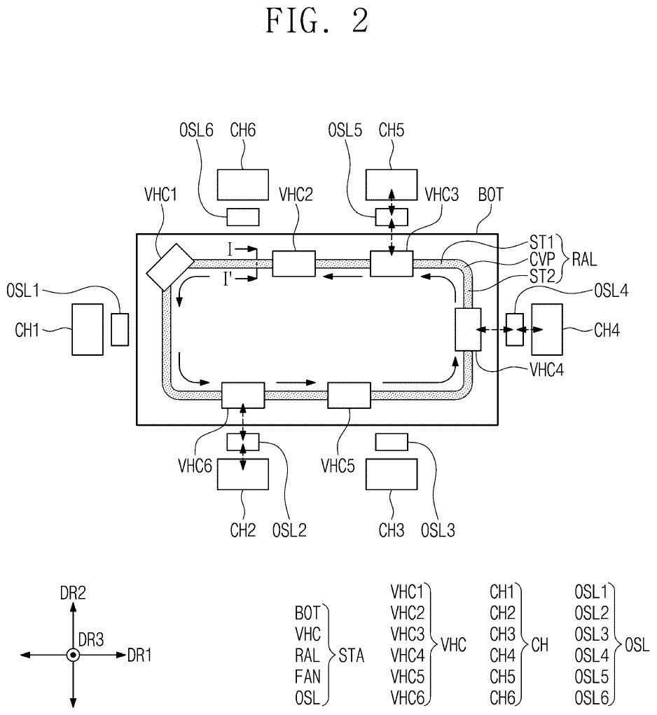

FIG. 2 is a view illustrating a plurality of vehicles and a rail disposed within the booth shown in FIG. 1.

As an example, FIG. 2 is illustrated as a plan view.

Referring to FIGS. 1 and 2, the substrate transfer apparatus STA may include a rail RAL and a plurality of vehicles VHC. The rail RAL and the vehicles VHC may be disposed within the booth BOT.

The rail RAL may have a closed-loop shape. The rail RAL may extend along edges of the booth BOT within the booth BOT. The rail RAL may include a plurality of first straight sections ST1, a plurality of second straight sections ST2, and a plurality of curved sections CVP. The first and second straight sections ST1 and ST2 may extend in a straight shape, and the curved sections CVP may extend in a curved shape.

The two first straight sections ST1 may extend parallel to the first direction DR1. The two second straight sections ST2 may be adjacent to both ends of the first straight sections ST1, disposed outward from both ends of the first straight sections ST1, and may extend parallel to the second direction DR2. The curved sections CVP may extend from both ends of the first straight sections ST1 toward both ends of the second straight sections ST2. The curved sections CVP may have a convex curved shape directed outward.

The vehicles VHC may be disposed on the rail RAL and may move along the rail RAL. As an example, six vehicles VHC are illustrated, but the number of vehicles VHC is not limited thereto.

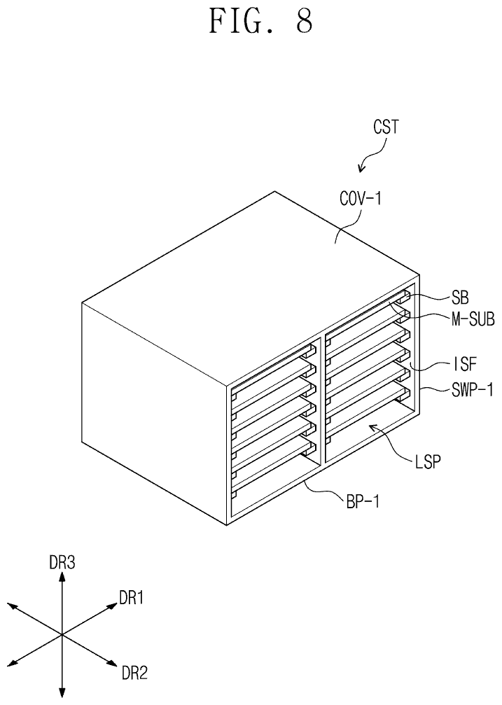

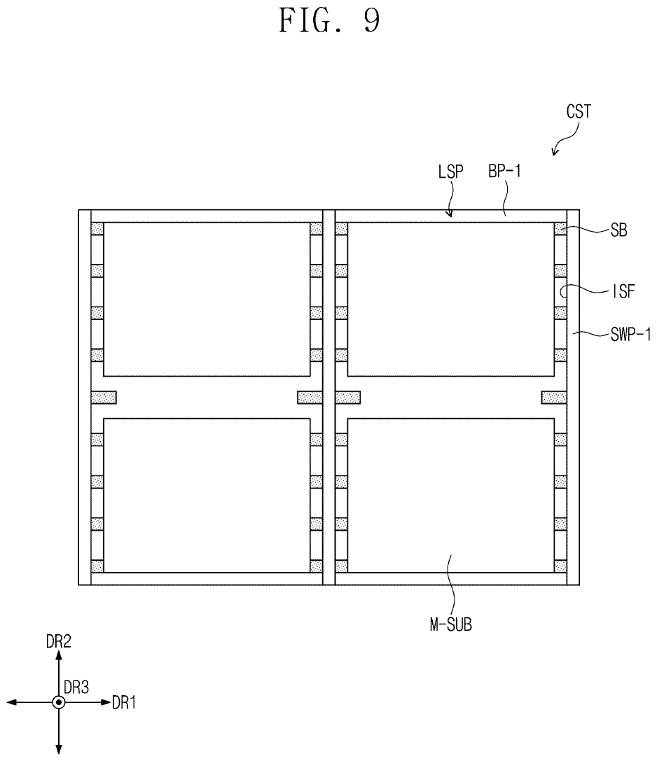

The vehicles VHC may include first to sixth vehicles VHC1 to VHC6. The substrate loading parts (shown in FIGS. 8 and 9 below) may be disposed on the first to sixth vehicles VHC1 to VHC6, and substrates may be loaded onto the substrate loading parts. The first to sixth vehicles VHC1 to VHC6 may move along the rail RAL, and substrates may be transferred by the first to sixth vehicles VHC1 to VHC6.

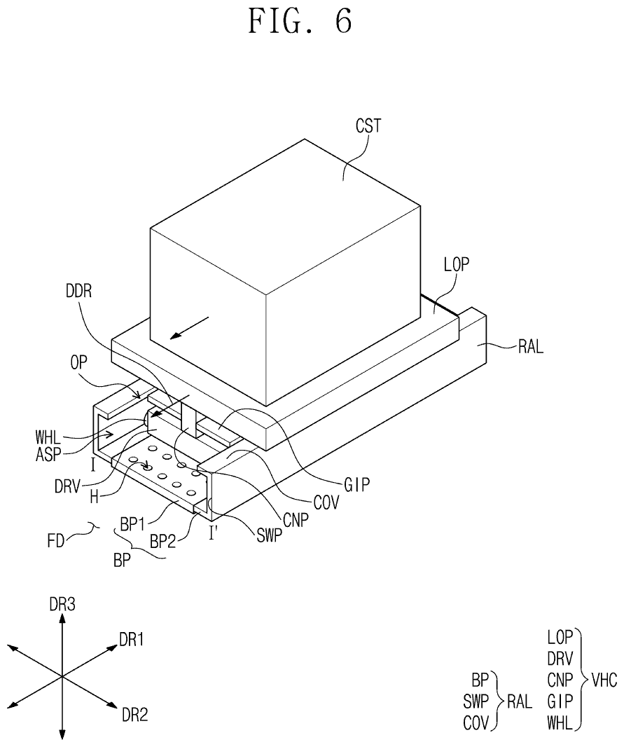

As an example, the first to sixth vehicles VHC1 to VHC6 are illustrated in block shapes, and the more detailed configuration of the first to sixth vehicles VHC1 to VHC6 will be shown in FIG. 6 below.

Substrates processed in the first to sixth process chambers CH1 to CH6 may be transferred to the first to sixth vehicles VHC1 to VHC6 within the booth BOT. The substrates may be moved along the rail RAL by the first to sixth vehicles VHC1 to VHC6 and transferred to the first to sixth process chambers CH1 to CH6.

The first to sixth outer substrate loading parts OSL1 to OSL6 may transfer the substrates disposed in the first to sixth process chambers CH1 to CH6 to the first to sixth vehicles VHC1 to VHC6. Additionally, the first to sixth outer substrate loading parts OSL1 to OSL6 may transfer the substrates loaded on the first to sixth vehicles VHC1 to VHC6 to the first to sixth process chambers CH1 to CH6.

Using the first vehicle VHC1 as an example, one of the substrates to be processed may be transferred from outside the booth BOT to inside the booth BOT and loaded onto the first vehicle VHC1. Within the booth BOT, the substrate disposed on the first vehicle VHC1 may be transferred to the first process chamber CH1 through the first outer substrate loading part OSL1. In the first process chamber CH1, a predetermined device may be disposed on the substrate.

The substrate processed in the first process chamber CH1 may be transferred to the first vehicle VHC1 through the first outer substrate loading part OSL1. The first vehicle VHC1 onto which the substrate processed in the first process chamber CH1 is loaded may move along the rail RAL to a position adjacent to the second process chamber CH2.

Subsequently, the substrate disposed on the first vehicle VHC1 may be transferred to the second process chamber CH2 through the second outer substrate loading part OSL2. In the second process chamber CH2, a predetermined device may be disposed on the substrate. A subsequent process for the substrate processed in the first process chamber CH1 may be performed in the second process chamber CH2.

The substrate processed in the second process chamber CH2 may be transferred to the first vehicle VHC1 through the second outer substrate loading part OSL2, and the first vehicle VHC1 may move along the rail RAL to a position adjacent to the third process chamber CH3. Subsequently, the substrate disposed on the first vehicle VHC1 may be transferred to the third process chamber CH3 through the third outer substrate loading part OSL3, and a subsequent process for the substrate processed in the second process chamber CH2 may be performed in the third process chamber CH3.

Through the same operations, the substrate disposed on the first vehicle VHC1 may be transferred to the sixth process chamber CH6, and the substrate, which is completely processed in the sixth process chamber CH6, may be loaded onto the first vehicle VHC1. After the completely processed substrate is loaded onto the first vehicle VHC1, the substrate may be returned to outside the booth BOT.

Through similar operations, substrates disposed on the second to sixth vehicles VHC2 to VHC6 may be transferred to the first to sixth process chambers CH1 to CH6, and processes for the substrates may be performed in the first to sixth process chambers CH1 to CH6.

Although not shown, a plurality of robot arms may be disposed between the booth BOT and the first to sixth outer substrate loading parts OSL1 to OSL6, as well as between the first to sixth outer substrate loading parts OSL1 to OSL6 and the first to sixth process chambers CH1 to CH6. The substrates may be transferred by the robot arms. The robot arms may also be disposed within the first to sixth outer substrate loading parts OSL1 to OSL6. This configuration will be described in detail below.

Although not shown, gates may be defined in the booth BOT as pathways for the movement of substrates.

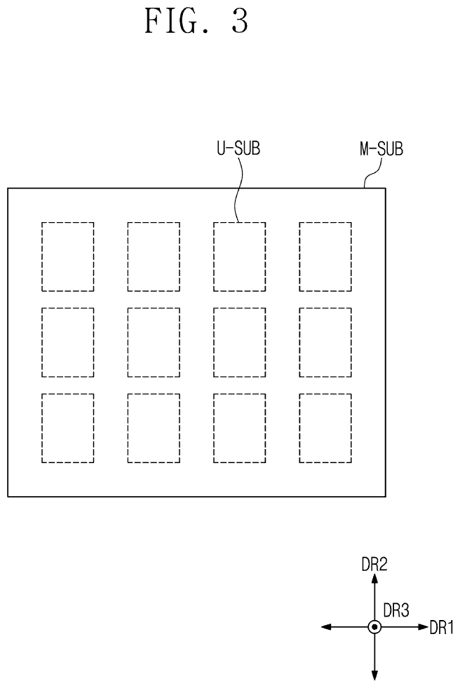

FIG. 3 is a view illustrating an example of a planar configuration of the substrate to be loaded onto the first to sixth vehicles VHC1 to VHC6 shown in FIG. 2.

Referring to FIG. 3, a substrate M-SUB may be loaded onto each of the first to sixth vehicles VHC1 to VHC6. Hereinafter, the substrate M-SUB is defined as a mother substrate. The mother substrate M-SUB may extend longer in the first direction DR1 than in the second direction DR2. The mother substrate M-SUB may include a plurality of unit substrates U-SUB.

The unit substrates U-SUB may be arranged in the first direction DR1 and the second direction DR2. The unit substrates U-SUB may extend longer in the second direction DR2 than in the first direction DR1. Through the aforementioned process chambers CH, pixels may be disposed on the unit substrates U-SUB. After pixels are disposed on the unit substrates U-SUB, the unit substrates U-SUB may be cut and separated from the mother substrate M-SUB. The pixels may be disposed on each of the unit substrates U-SUB to manufacture a display panel.

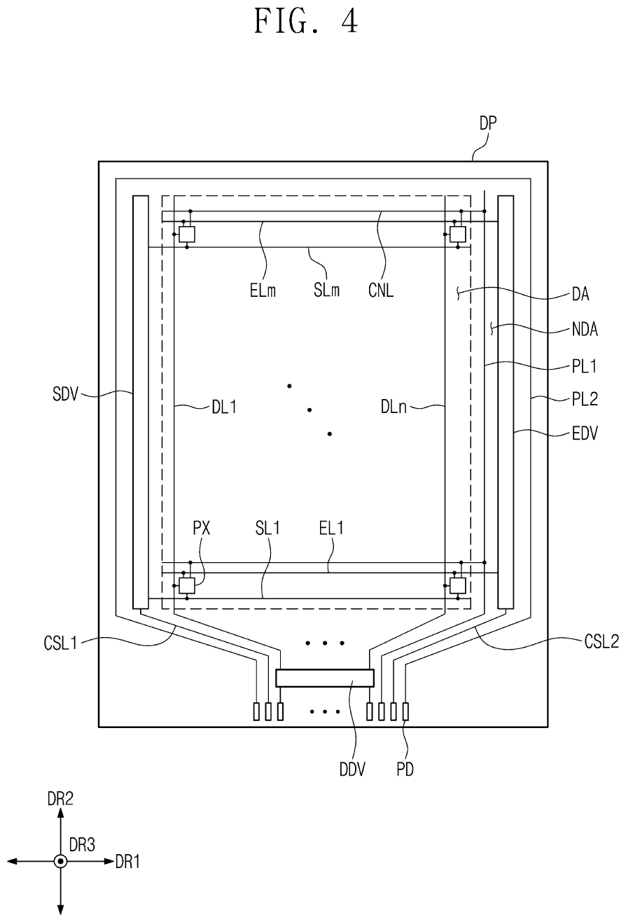

FIG. 4 is a view exemplarily illustrating a configuration of the display panel manufactured with the pixels disposed on each of the unit substrates shown in FIG. 3.

Referring to FIG. 4, the display panel DP may have a rectangular shape with long sides extending in the first direction DR1 and short sides extending in the second direction DR2, but the shape of the display panel DP is not limited thereto. The display panel DP may include a display area DA and a non-display area NDA surrounding the display area DA.

The display panel DP may be a light emission-type display panel. The display panel DP may be an organic light-emitting display panel or an inorganic light-emitting display panel. An emission layer of the organic light-emitting display panel may include an organic light-emitting material. An emission layer of the inorganic light-emitting display panel may include a quantum dot, a quantum rod, and the like. Hereinafter, the display panel DP is described as the organic light-emitting display panel.

The display panel DP may include a plurality of pixels PX, a plurality of scan lines SL1 to SLm, a plurality of data lines DL1 to DLn, a plurality of light emission lines EL1 to ELm, first and second control lines CSL1 and CSL2, first and second power lines PL1 and PL2, connection lines CNL, and a plurality of pads PD. Here, m and n are natural numbers.

The pixels PX may be disposed in the display area DA. Each of a scan driver SDV and a light emission driver EDV may be disposed in the non-display area NDA adjacent to each of the long sides of the display panel DP. A data driver DDV may be disposed in the non-display area NDA adjacent to one of the short sides of the display panel DP. In the plan view, the data driver DDV may be adjacent to a lower end of the display panel DP.

The scan lines SL1 to SLm may extend in the second direction DR2 and be connected to the pixels PX and the scan driver SDV. The data lines DL1 to DLn may extend in the first direction DR1 and be connected to the pixels PX and the data driver DDV. The emission lines EL1 to ELm may extend in the second direction DR2 and be connected to the pixels PX and the emission driver EDV.

The first power line PL1 may extend in the first direction DR1 and be disposed in the non-display area NDA. The first power line PL1 may be disposed between the display area DA and the light emission driver EDV.

The connection lines CNL may extend in the second direction DR2 and be arranged in the first direction DR1. The connection lines CNL may be connected to the first power line PL1 and the pixels PX. A first voltage may be applied to the pixels PX through the first power line PL1 and the connection lines CNL which are connected to each other.

The second power line PL2 may be disposed in the non-display area NDA. The second power line PL2 may extend along the long sides of the display panel DP and another short side of the display panel DP in which the data driver DDV is not disposed. The second power line PL2 may be disposed at the outside of the scan driver SDV and the light emission driver EDV.

Although not illustrated, the second power line PL2 may extend toward the display area DA and be connected to the pixels PX. A second voltage having a lower level than the first voltage may be applied to the pixels PX via the second power line PL2.

The first control line CSL1 may be connected to the scan driver SDV and extend toward the lower end of the display panel DP in a plan view. The second control line CSL2 may be connected to the light emission driver EDV and extend toward the lower end of the display panel DP in a plan view. The data driver DDV may be disposed between the first control line CSL1 and the second control line CSL2.

The pads PD may be disposed on the display panel DP. The pads PD may be disposed closer to the lower end of the display panel DP than is the data driver DDV. The data driver DDV, the first power line PL1, the second power line PL2, the first control line CSL1, and the second control line CSL2 may be connected to the pads PD. The data lines DL1 to DLn may be connected to the data driver DDV, and the data driver DDV may be connected to pads PD corresponding to the data lines DL1 to DLn.

Although not illustrated, a timing controller for controlling the operations of the scan driver SDV, the data driver DDV, and the light emission driver EDV and a voltage generation part for generating the first and second voltages may be disposed on a printed circuit board. The timing controller and the voltage generator may be connected to the corresponding pads PD through a printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The emission driver EDV may generate a plurality of emission signals, and the emission signals may be applied to the pixels PX through the emission lines EL1 to ELm.

The pixels PX may receive the data voltages in response to the scan signals. The pixels PX may emit light having luminance corresponding the data voltages in response to the emission signals to display an image. An emission time of the pixels PX may be controlled by the emission signals.

Each of the unit substrates U-SUB illustrated in FIG. 3 may correspond to the display panel DP illustrated in FIG. 44.

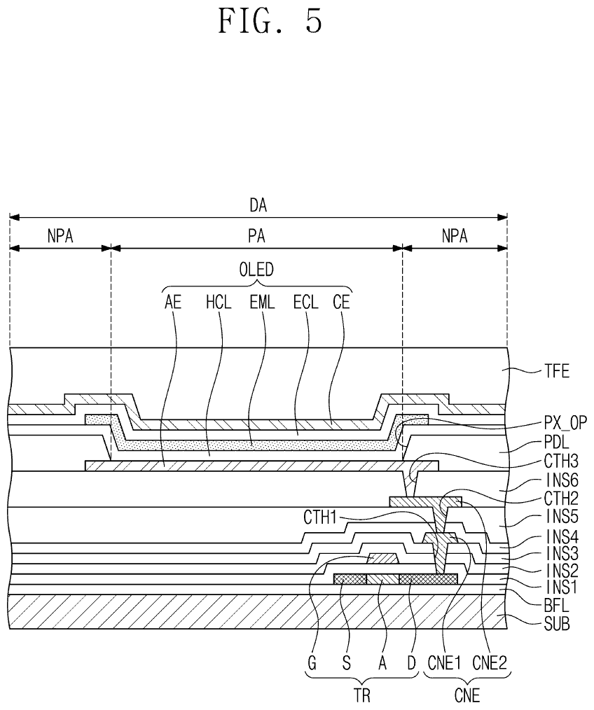

FIG. 5 is a view illustrating an example of a cross-section of a pixel shown in FIG. 4.

Referring to FIG. 5, the pixel PX may be disposed on the substrate SUB and include a transistor TR and a light-emitting element OLED. The substrate SUB may be defined by each of the unit substrates U-SUB shown in FIG. 3. The light-emitting element OLED may include a first electrode AE, a second electrode CE, a hole control layer HCL, an electron control layer ECL, and a light-emitting layer EML. The first electrode AE may be an anode electrode, and the second electrode CE may be a cathode electrode.

The transistor TR and the light-emitting element OLED may be disposed on the substrate SUB. One transistor TR is illustratively shown in the drawing, but substantially, the pixel PX may include a plurality of transistors and at least one capacitor to drive the light-emitting element OLED.

The display area DA may include an emission area PA corresponding to the pixel PX and a non-emission area NPA around the emission area PA. The light-emitting element OLED may be disposed in the emission area PA.

A buffer layer BFL may be disposed on the substrate SUB, and the buffer layer BFL may be an inorganic layer. A semiconductor pattern may be disposed on the buffer layer BFL. The semiconductor pattern may include polysilicon. However, the embodiment of the invention is not limited thereto, and the semiconductor pattern may include amorphous silicon or a metal oxide.

The semiconductor pattern may be doped with N-type dopants or P-type dopants. The semiconductor pattern may include a high-doped region and a low-doped region. The highly-doped region may have conductivity greater than that of the low-doped region and may substantially serve as source and drain electrodes of the transistor TR. The low-doped region may effectively correspond to an active (or channel) of the transistor.

A source S, an active A, and a drain D of the transistor TR may be provided from the semiconductor pattern. A first insulating layer INS1 may be arranged on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may be disposed between the transistor TR and the light-emitting element OLED and connect the transistor TR to the light-emitting element OLED. The connection electrode CNE may include a first connection electrode CNE1 and a second connection electrode CNE2.

The first connection electrode CNE1 may be disposed on the third insulating layer INS3 and connected to the drain D through a first contact hole CTH1 defined in the first to third insulating layers INS1 to INS3. A fourth insulating layer INS4 may be disposed on the first connection electrode CNE1. A fifth insulating layer INS5 may be disposed on the fourth insulating layer INS4.

The second connection electrode CNE2 may be disposed on the fifth insulating layer INS5. The second electrode CNE2 may be connected to the first connection electrode CNE1 through a second contact hole CTH2 defined in the fifth insulating layer INS5. A sixth insulating layer INS6 may be disposed on the second connection electrode CNE2. Each of the first insulating layer INS1 to the sixth insulating layer INS6 may be an inorganic layer or an organic layer.

The first electrode AE may be disposed on the sixth insulating layer INS6. The first electrode AE may be connected to the second connection electrode CNE2 through a third contact hole CTH3 defined in the sixth insulating layer INS6. A pixel defining layer PDL that exposes a predetermined portion of the first electrode AE may be disposed on the first electrode AE and the sixth insulating layer INS6. An opening portion PX_OP for exposing a predetermined portion of the first electrode AE may be defined in the pixel defining PDL.

The hole control layer HCL may be disposed on the first electrode AE and the pixel defining layer PDL. A hole control layer HCL may be disposed in common in the emission area PA and the non-emission area NPA. The hole control layer HCL may include a hole transport layer and a hole injection layer.

The emission layer EML may be disposed on the hole control layer HCL. The emission layer EML may be disposed on an area corresponding to the opening OP. The emission layer EML may include organic and/or inorganic materials. The emission layer EML may emit one of red light, green light, and blue light.

The electron control layer ECL may be disposed on the emission layer EML and the hole control layer HCL. The electron control layer ECL may be disposed in common in the emission area PA and the non-emission area NPA. The electron control layer ECL may include an electron transport layer and an electron injection layer. The second electrode CE may be disposed on the electronic control layer ECL. The second electrode CE may be commonly disposed on the pixels PX.

A thin film encapsulation layer TFE may be disposed on the light-emitting element OLED. The thin film encapsulation layer TFE may be disposed on the second electrode CE to cover the pixel PX. The thin film encapsulation layer TFE may include at least two inorganic layers and an organic layer between the inorganic layers. The inorganic layers may protect the pixel PX from moisture/oxygen. The organic layer may protect the pixel PX from impurities such as dust particles.

A first voltage may be applied to the first electrode AE through the transistor TR, and a second voltage having a lower level than the first voltage may be applied to the second electrode CE. A hole and an electron injected into the light-emitting layer EML are coupled to each other to form an exciton, and while the exciton is transited to a ground state, the light-emitting element OLED may emit light.

The substrate SUB may be provided to the process chambers CH, layers from the buffer layer BFL to the thin film encapsulation layer TFE may be sequentially disposed on the substrate in the above-described process chambers CH. In addition, the substate SUB may be transferred by the above-described vehicles VHC.

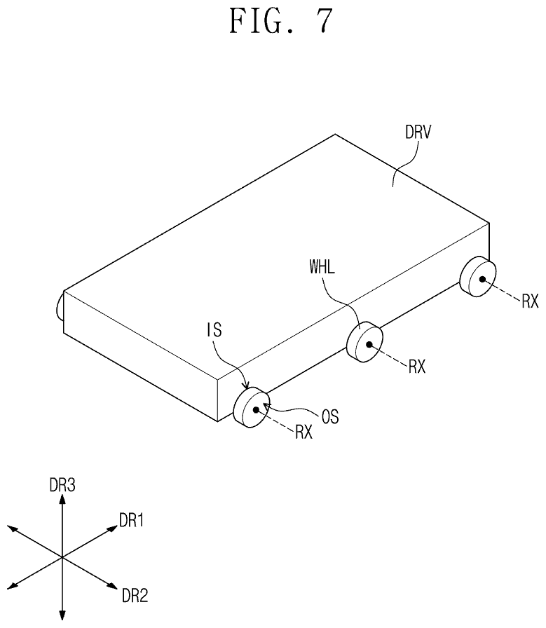

FIG. 6 is a view illustrating a cross-section taken along line I-I′ shown in FIG. 2. FIG. 7 is a view separately illustrating a driving part and wheels disposed within the rail shown in FIG. 6.

For example, FIGS. 6 and 7 are shown as perspective views.

The configurations of first to sixth vehicles VHC1 to VHC6 may be identical. Accordingly, the configuration of the second vehicle VHC2, as shown along line I-I′, will be described below. Also, for the convenience of explanation, the second vehicle VHC2, shown taken along line I-I′, is depicted and described as the vehicle VHC.

Referring to FIGS. 6 and 7, the substrate transfer device STA may further include an inner substrate loading part CST disposed on the vehicle VHC. The inner substrate loading part CST may be defined as a cassette. The above-described mother substrates M-SUB may be loaded onto the inner substrate loading part CST. The more specific configuration of the inner substrate loading part CST will be described in detail below with reference to FIGS. 8 and 9.

The vehicle VHC may include a loading plate LOP, a driving part DRV, a connecting part CNP, a guide plate GIP, and a plurality of wheels WHL.

The loading plate LOP may have a flat shape defined by the first direction DR1 and the second direction DR2. The inner substrate loading part CST may be disposed on the loading plate LOP. The inner substrate loading part CST may be fixed to the loading plate LOP.

The driving part DRV may be disposed below the loading plate LOP. The driving part DRV may extend longer in the first direction DR1 than in the second direction DR2. The driving part DRV may be connected to the loading plate LOP.

The connecting part CNP may be disposed below the loading plate LOP, and the driving part DRV disposed below the connecting part CNP. The connecting part CNP may extend in the first direction DR1. The connecting part CNP may be disposed between the loading plate LOP and the driving part DRV, connecting the loading plate LOP and the driving part DRV to each other. Thus, the driving part DRV may be connected to the loading plate LOP through the connecting part CNP. The guide plate GIP may be disposed between the loading plate LOP

and the driving part DRV. The guide plate GIP may be connected to both sides of the connecting part CNP, which are opposite in the second direction DR2. The guide plate GIP may have a flat shape defined by the first direction DR1 and the second direction DR2. The guide plate GIP may extend in the first direction DR1.

The wheels WHL may be connected to both sides of the driving part DRV, which are opposite in the second direction DR2. The wheels WHL may be arranged in the first direction DR1 on both sides of the driving part DRV. The wheels WHL may have a circular shape when viewed in the second direction DR2. The wheels WHL may include inner surfaces IS, which face the driving part DRV in the second direction DR2, and outer surfaces OS, which are defined by the opposite surfaces of the inner surfaces IS.

The wheels WHL may rotate in the same direction. The driving part DRV may transmit driving force to the wheels WHL to cause the wheels WHL to rotate. Each of the wheels WHL may rotate around a rotational axis RX, which overlaps the center of the wheel WHL and extend parallel to the second direction DR2. For example, when viewed in the second direction DR2, the wheel WHL may rotate counterclockwise around the rotational axis RX.

The rotational axis RX may be defined adjacent to a lower side of the driving part DRV. That is, the center of the wheel WHL, which overlaps with the rotational axis RX, may be adjacent to the lower side of the driving part DRV.

According to the rotation of the wheels WHL, the guide plate GIP and the loading plate LOP, connected to the connecting part CNP may move, and the inner substrate loading part CST on the loading plate LOP may move. According to the rotation of the wheels WHL, a traveling direction DDR of the loading plate LOP (for example, one direction of the bidirectional first direction DR1) may be determined, and a front direction FD of the loading plate LOP relative to the traveling direction DDR may be defined. The front direction FD may be defined as a space in front of the loading plate LOP with respect to the traveling direction DDR.

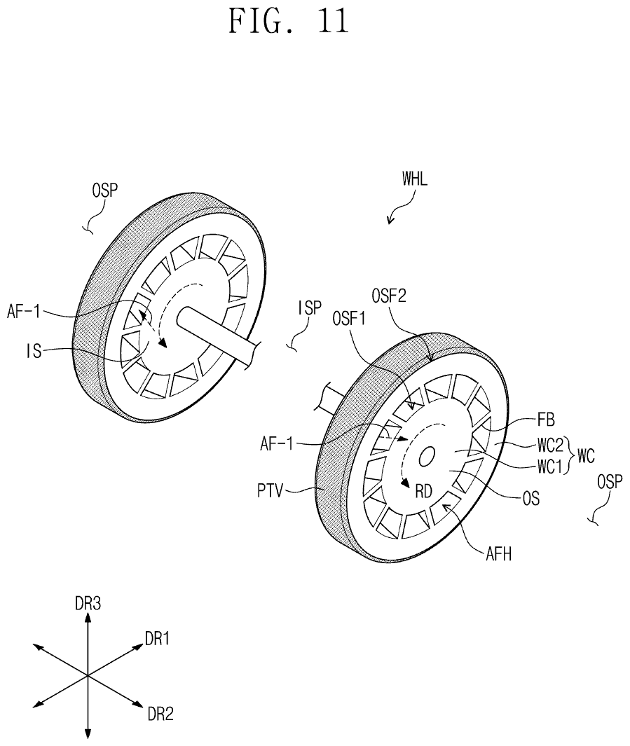

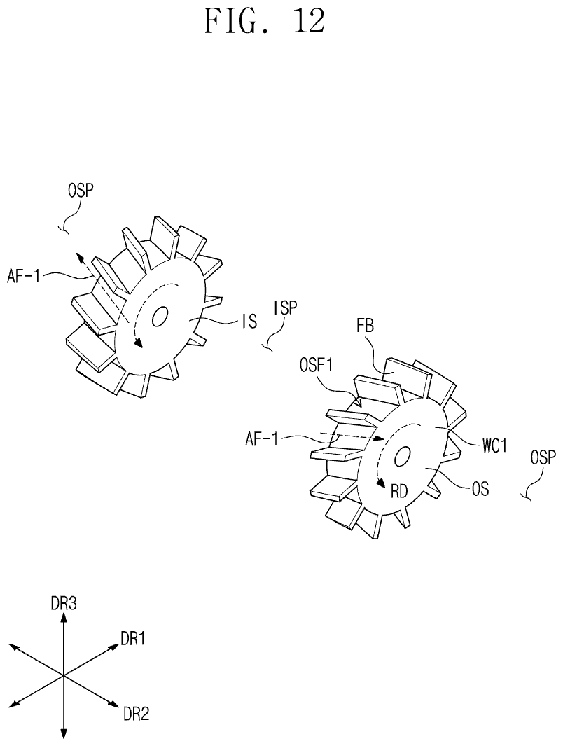

For example, the wheels WHL are schematically shown, but the wheels WHL may actually have a fan shape. The detailed configuration of the wheels WHL will be described in detail below with reference to FIGS. 11 and 12.

The rail RAL may be disposed below the loading plate LOP and may extend in the first direction DR1. In the rail RAL, an accommodation space ASP that extends in the first direction DR1 may be defined. The driving part DRV and the wheels WHL may be disposed within the accommodation space ASP.

An opening OP may be defined on an upper portion of the rail RAL. The opening OP may be defined continuously in the accommodation space ASP. In a plan view, the driving part DRV, the connecting part CNP, and the guide plate GIP may be disposed to overlap with the opening OP. The guide plate GIP may be disposed within the opening OP.

The driving part DRV may be connected to the loading plate LOP via the opening OP. For example, the connecting part CNP, connected to the driving part DRV, may extend upward through the opening OP and be connected to the loading plate LOP disposed on the rail RAL.

The rail RAL may include a bottom part BP, a plurality of sidewalls SWP, and a plurality of cover parts COV. The bottom part BP may have a flat shape defined by the first and second directions DR1 and DR2. The bottom part BP may extend in the first direction DR1. The bottom part BP may be disposed below the driving part DRV and the wheels WHL. A plurality of holes H may be defined in the bottom part BP.

The bottom part BP may include a first bottom part BP1 and second bottom part BP2, which are connected to both sides of the first bottom part BP1 in the second direction DR2. The holes H may be defined in the first bottom part BP1.

The first bottom part BP1 may be disposed below the driving part DRV, and in a plan view, may overlap with the driving part DRV. The second bottom part BP2 may be disposed below the wheels WHL, and in a plan view, may overlap with the wheels WHL.

The driving part DRV may be disposed on the first bottom part BP1. The wheels WHL may be disposed on the second bottom part BP2. When the wheels WHL rotate, the driving part DRV may move along the first bottom part BP1, and the wheels WHL may move along the second bottom part BP2.

The sidewalls SWP may extend upward from the third direction DR3 from both sides of the second bottom part BP2, which are opposite in the second direction DR2. The sidewalls SWP may extend in the first direction DR1. The sidewalls SWP may have a flat shape defined by the first and third directions DR1 and DR3. The sidewalls SWP may face the wheels WHL.

The cover parts COV may extend toward each other from upper ends of the sidewalls SWP. The cover parts COV may extend in the first direction DR1 to face each other in the second direction DR2. The cover parts COV may have a flat shape defined by the first and second directions DR1 and DR2.

The accommodation space ASP may be defined as a space between the bottom part BP, the sidewalls SWP, and the cover parts COV. The opening OP may be defined as a space between the cover parts COV. The guide plate GIP may be disposed between the cover parts COV. When the wheels WHL rotate, the guide plate GIP may move along the opening OP between the cover parts COV.

FIG. 8 is a view illustrating a more detailed configuration of an inner substrate loading part shown in FIG. 6. FIG. 9 is a top view illustrating a mother substrate disposed in loading spaces shown in FIG. 8.

For example, in FIG. 9, a cover part COV-1 is omitted.

Referring to FIGS. 8 and 9, a plurality of loading spaces LSP may be defined in the inner substrate loading part CST. The loading spaces LSP may be arranged in the first direction DR1 and defined in the inner substrate loading part CST so as to be opened in the second direction DR2. The mother substrate M-SUB may be disposed within each of the loading spaces LSP.

For example, in FIG. 6, the inner substrate loading part CST is shown as a box shape, but substantially, the loading spaces LSP opened in the second direction DR2 may be defined in the inner substrate loading part CST, as shown in FIG. 8.

The inner substrate loading part CST may include a bottom part BP-1, a plurality of sidewalls SWP-1, a cover part COV-1, and a plurality of support bars SB. The bottom part BP-1 may have a flat shape defined by the first and second directions DR1 and DR2. The bottom part BP-1 may extend longer in the first direction DR1 than in the second direction DR2.

The sidewalls SWP-1 may be arranged in the first direction DR1. The sidewalls SWP-1 may have a flat shape defined by the second and third directions DR2 and DR3. The sidewalls SWP-1 may extend upward from the bottom part BP-1. The sidewalls SWP-1 may extend upward from both sides of the bottom part BP-1, opposite to each other in the first direction, as well as from the center of the bottom part BP-1.

The cover part COV-1 may be disposed on upper ends of the sidewalls SWP-1 to cover them. The cover part COV-1 may extend longer in the first direction DR1 than in the second direction DR2. The cover part COV-1 may have a flat shape defined by the first and second directions DR1 and DR2. The cover part COV-1 may extend in the first direction DR1 from the upper ends of the sidewalls SWP-1.

The loading space LSP may be defined as the space between the bottom part BP-1, the sidewalls SWP-1, and the cover part COV-1.

The support bars SB may be connected to the sidewalls SWP-1. The support bars SB may be connected to inner surfaces ISF of the sidewalls SWP-1, which face each other in the first direction DR1. The support bars SB may be arranged in the second direction DR2. The mother substrates M-SUB may be disposed on the support bars SB.

The mother substrates M-SUB may be disposed on the support bars SB within the loading spaces LSP and loaded onto the inner substrate loading part CST. According to the above configuration, the mother substrates M-SUB may be loaded onto the inner substrate loading part CST and transferred by the vehicles VHC.

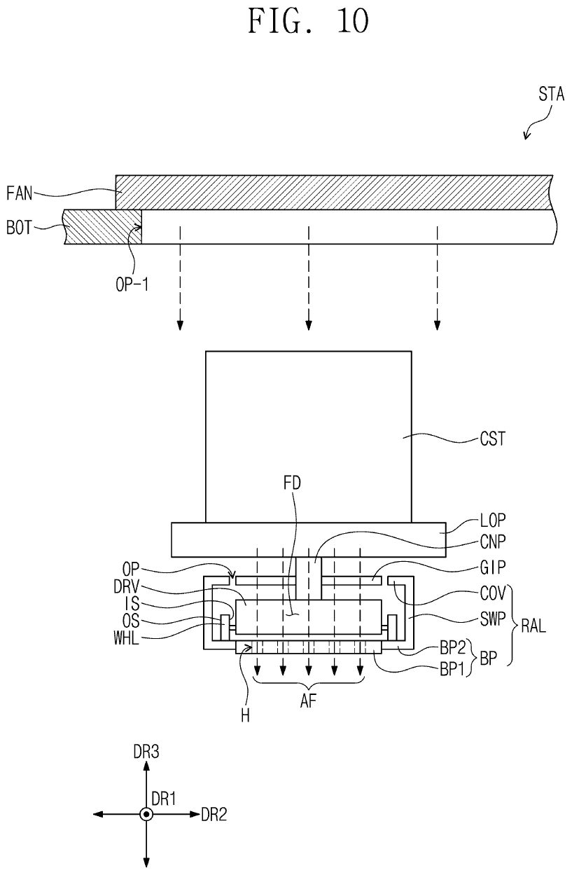

FIG. 10 is a front view illustrating the vehicle and rail shown in FIG. 6, as seen from a front defined by the traveling direction.

For example, in FIG. 10, the holes H defined in the bottom part BP are shown with dotted lines. Additionally, a ceiling of the booth BOT and the blower FAN disposed on the booth BOT are schematically shown.

Referring to FIG. 10, in a planar view, the driving part DRV may overlap with the first bottom part BP1. In a planar view, the holes H may be defined to overlap with the driving part DRV.

In a planar view, the wheels WHL may overlap with the second bottom part BP2. The wheels WHL may be disposed on the second bottom part BP2 and may be in contact with a top surface of the second bottom part BP2. The wheels WHL may rotate and move along the top surface of the second bottom part BP2.

The sidewalls SWP may face outer surfaces OS of the wheels WHL. The wheels WHL may be spaced apart from the sidewalls SWP. Thus, a predetermined space may be defined between the sidewalls SWP and the outer surfaces OS of the wheels WHL.

The guide plate GIP may be disposed in the opening OP and disposed in the same plane as the cover parts COV.

The blower FAN and the ceiling of the booth BOT may be disposed on the loading plate LOP. The fans (not shown) of the blower FAN may blow air into the booth BOT through the opening OP-1 of the booth BOT. Thus, an airflow AF may be provided within the booth BOT.

The airflow AF may be generated from the top to the bottom. The airflow AF may be provided toward the rail RAL by the blower FAN. The airflow AF may be discharged through the holes H defined in the first bottom part BP1.

FIG. 11 is a view illustrating a detailed configuration of a pair of wheels disposed in a second direction, selected from wheels shown in FIG. 7; FIG. 12 is a view illustrating the wheels shown in FIG. 11, with a second wheel core removed and a first wheel core and fan blades separately illustrated.

For example, FIGS. 11 and 12 are shown as perspective views.

Referring to FIGS. 11 and 12, the wheels WHL may have a symmetrical shape with respect to a plane defined by the first and third directions DR1 and DR3 and may have substantially the same shape. Accordingly, the configuration of the wheel WHL disposed on the right side in FIGS. 11 and 12 will be exemplarily described below.

The wheel WHL may include a wheel core WC and a protective layer PTV. When viewed in the second direction DR2, an outer circumferential surface OSF2 of the wheel core WC may have a circular shape. The wheel core WC may include a metal such as stainless steel or aluminum.

The protective layer PTV may be disposed to surround the outer circumferential surface OSF2 of the wheel core WC when viewed in the second direction DR2. The protective layer PTV may have a predetermined elasticity and may protect the wheel core WC. The protective layer PTV may include an elastic material such as urethane.

The wheel core WC may include a first wheel core WC1, a second wheel core WC2, and a plurality of fan blades FB. When viewed in the second direction DR2, the first wheel core WC1 may have a circular shape. The first wheel core WC1 may include a first outer circumferential surface OSF1 corresponding to a circular periphery of the first wheel core WC1.

The second wheel core WC2 may be disposed to surround the first outer circumferential surface OSF1 of the first wheel core WC1. When viewed in the second direction DR2, the second wheel core WC2 may have a ring shape. The second wheel core WC2 may include a second outer circumferential surface OSF2 corresponding to a circular periphery of the second wheel core WC2. The second outer circumferential surface OSF2 may define the outer circumferential surface OSF2 of the wheel core WC.

When viewed in the second direction DR2, the protective layer PTV may be disposed to surround the second outer circumferential surface OSF2 of the second wheel core WC2. The protective layer PTV may be defined as a tire.

The fan blades FB may be disposed between the first wheel core WC1 and the second wheel core WC2. The fan blades FB may be connected to the first wheel core WC1 and the second wheel core WC2. For example, each of the fan blades FB may be integrally provided (i.e., monolithic) with the first wheel core WC1 and the second wheel core WC2. The fan blade FB may have a flat plate shape. The fan blade FB may be disposed to be inclined with respect to the second direction DR2.

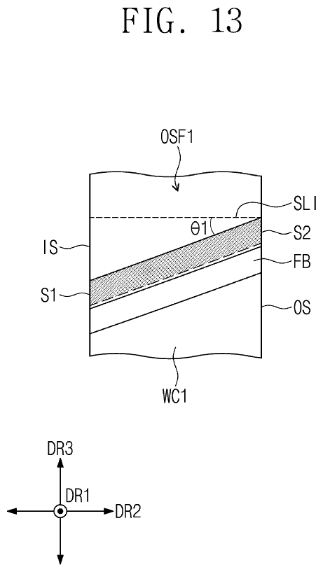

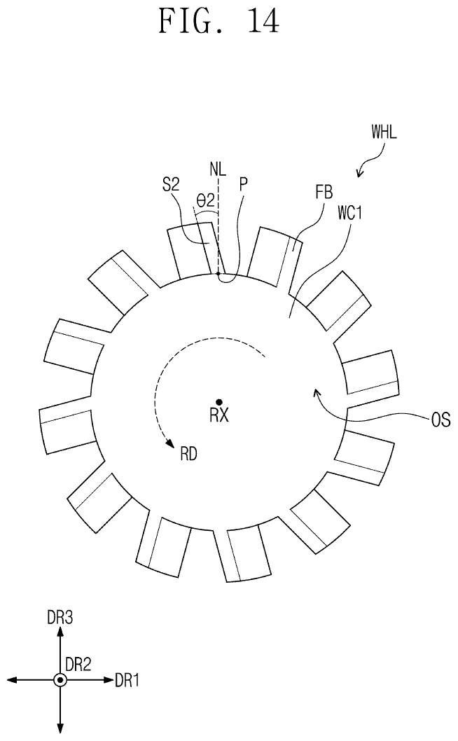

FIG. 13 is a front view illustrating one of the fan blades shown in FIG. 12. FIG. 14 is a view illustrating the first wheel core and the fan blades shown in FIG. 12, as viewed from the second direction, with the outer surface of the first wheel core visible.

FIG. 13 may be defined as a front view, and FIG. 14 may be defined as a side view.

Referring to FIGS. 12 and 13, when viewed in the first direction DR1, each of the fan blades FB may be disposed to be inclined at a first angle θ1 relative to the second direction DR2. For example, a contact portion between the first outer circumferential surface OSF1 and a lower side of the fan blade FB is illustrated in gray.

The fan blade FB may include a first side S1 adjacent to an inner surface IS of the wheel WHL and a second side S2 adjacent to an outer surface OS of the wheel WHL. The first side S1 adjacent to the inner surface IS and the second side S2 adjacent to the outer surface OS may correspond to both sides of the contact portion between the first outer circumferential surface OSF1 and the lower side of the fan blade FB.

When viewed in the first direction DR1, a reference line SL1 extending from the second side S2 of the fan blade FB in the second direction DR2 may be defined. The reference line SL1 may overlap the first outer circumferential surface OSF1. The reference line SL1 may extend in a direction perpendicular to the planes of the outer surface OS and the inner surface IS.

Each of the fan blades FB may be disposed to be inclined such that an acute angle is defined with respect to the reference line SL1. In other words, a first angle θ1 may be an acute angle. For example, the first angle θ1 may range from about 10 degrees to about 45 degrees.

The first side S1 and the second side S2 of each of the fan blades FB may be disposed at different heights when viewed in the first direction DR1 as shown in FIG. 13. For example, viewed in the first direction DR1, the first side S1 of each of the fan blades FB may be disposed lower than the second side S2 of each of the fan blades FB in the third direction DR3.

The number of fan blades FB in each wheel WHL may be 4n, where n is a natural number. For example, 12 fan blades FB are illustrated in each wheel WHL; however, the number of fan blades FB is not limited thereto.

Referring to FIGS. 12 and 14, when viewed in the second direction DR2, each of the fan blades FB may be disposed to be inclined such that a second angle θ2 is defined with respect to a normal line NL extending in a direction perpendicular to the rotation axis RX and crossing a contact portion P between the second side S2 and the outer surface OS. For example, the contact portion P between the fan blade FB (e.g., the second side S2) and the first outer circumferential surface OSF1 (e.g., the outer surface OS) is shown as a dotted line.

The second angle θ2 may be an acute angle. For example, the second angle θ2 may range from about 10 degrees to about 45 degrees. Each of the fan blades FB may be disposed to be inclined in the rotational direction RD of the wheel WHL relative to the normal line NL.

Referring to FIGS. 11 to 14, spaces defined between the fan blades FB may be defined as airflow holes AFH. When the wheels WHL rotate, airflow AF-1 may be generated by the fan blades FB, depending on the structure of the fan blades FB. When the wheels WHL rotate, the airflow AF-1 may be generated from an inner space ISP between the wheels WHL toward an outer space OSP of the wheels WHL, opposite to the inner space ISP.

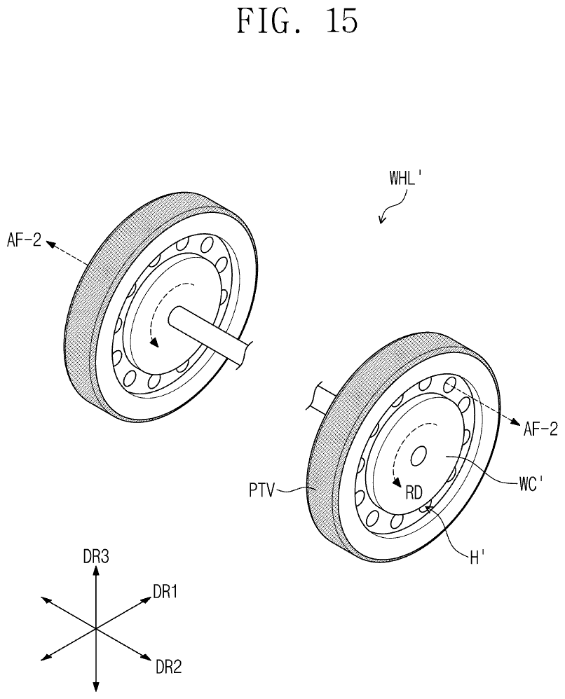

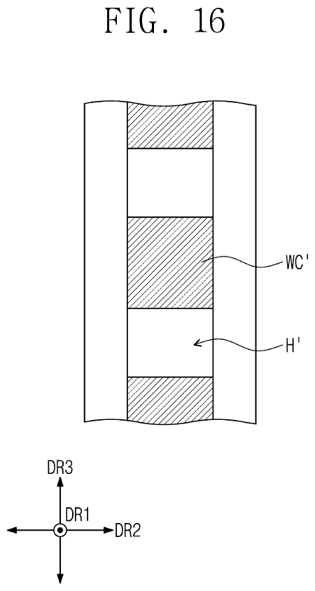

FIG. 15 is a perspective view of comparative wheels according to a comparative embodiment. FIG. 16 is a cross-sectional view of two adjacent holes in one of the comparative wheels shown in FIG. 15.

For example, FIG. 15 is a perspective view corresponding to the configurations in FIG. 11.

Referring to FIGS. 15 and 16, each of the comparative wheels WHL′ may include a comparative wheel core WC′ and a protective layer PTV surrounding an outer circumferential surface of the comparative wheel core WC′. A plurality of holes H′ may be defined in the comparative wheel core WC′ adjacent to the protective layer PTV. The holes H′ may extend parallel to the second direction DR2.

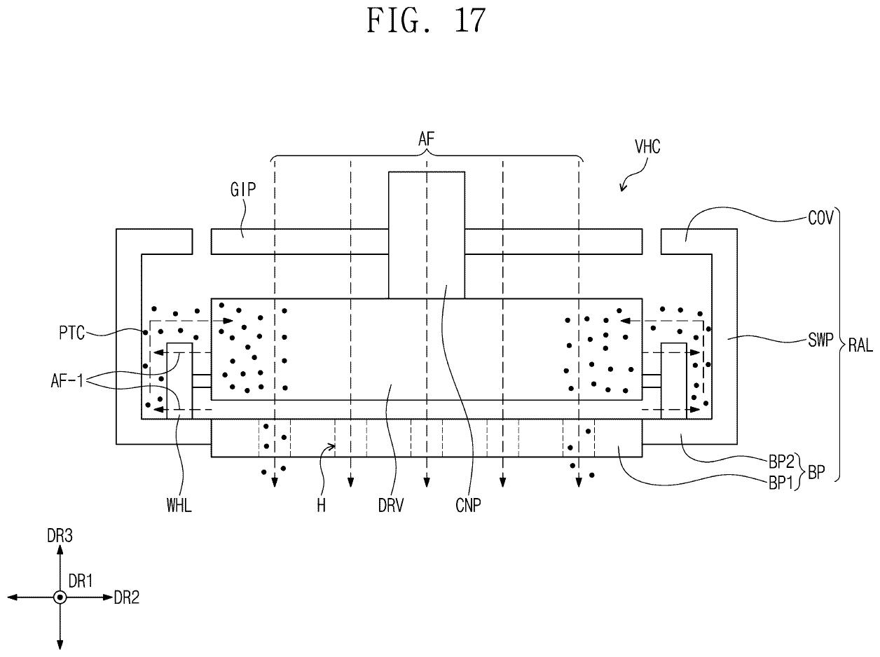

FIG. 17 is an enlarged view illustrating the vehicle and rail shown in FIG. 10.

For example, in FIG. 17, the inner substrate loading part CST and the loading plate LOP of the vehicle VHC are omitted, and airflow generated by the blower FAN is illustrated.

Referring to FIGS. 11, 12, and 17, when the wheels WHL rotate, friction may occur between the protective layers PTV and the second bottom part BP2. Due to abrasion on the protective layers PTV caused by the friction, particles PTC may be generated from the protective layers PTV. When the particles PTC are provided to the mother substrate M-SUB loaded onto the inner substrate loading part CST, the mother substrate M-SUB may be contaminated.

The particles PTC may be removed by airflow AF generated inside the booth BOT by the blower FAN. For example, when the airflow AF is discharged through holes H defined in the first bottom part BP1, the particles PTC may be discharged through the holes H along with the airflow AF.

The particles PTC generated from the protective layers PTV may accumulate on the second bottom part BP2 between the wheels WHL and the sidewalls SWP. The airflow AF may be generated toward the holes H and may not be provided on the second bottom part BP2 between the wheels WHL and the sidewalls SWP.

When the wheels WHL rotate, the airflow AF-1 directed outward of the wheels WHL may be generated by the fan blades FB. The airflow AF-1 generated by the fan blades FB may have a predetermined speed. The speed of the airflow AF-1 may correspond to the intensity of the airflow.

The airflow AF-1 generated by the fan blades FB may have a high speed capable of dispersing the particles PTC. The airflow AF-1 may disperse the particles PTC accumulated on the second bottom part BP2 between the wheels WHL and the sidewalls. In this case, the particles PTC may be discharged through the holes H by the airflow AF-1 and the airflow AF. Accordingly, the particles PTC may be more easily removed, preventing contamination of the mother substrates M-SUB.

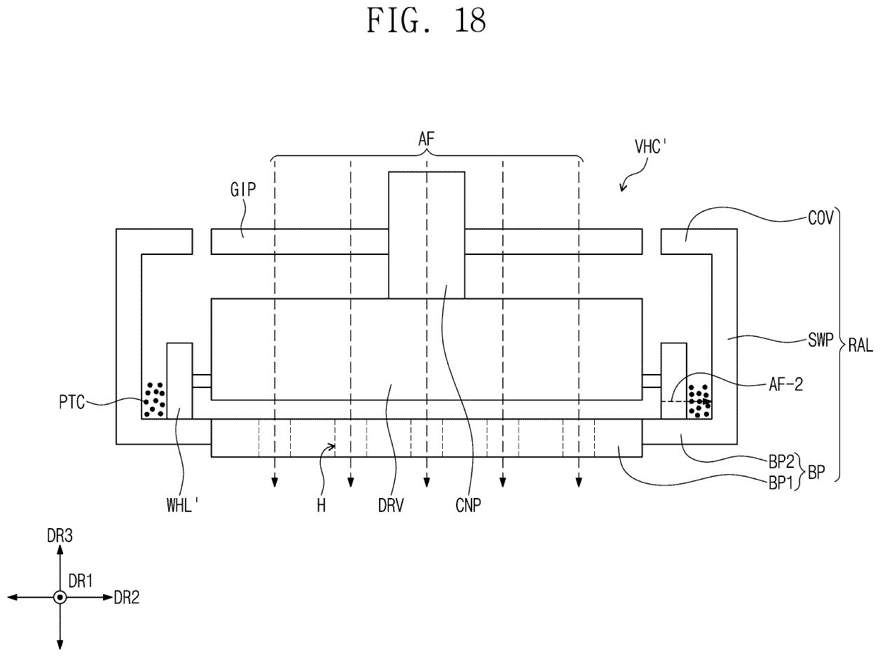

FIG. 18 is a view illustrating a comparative vehicle and rail including comparative wheels according to a comparative embodiment.

For example, FIG. 18 is a front view corresponding to the configurations in FIG. 17.

Referring to FIGS. 15, 16, and 18, the comparative vehicle VHC′ may include comparative wheels WHL′. Similar to the description in FIG. 17, particles PTC may accumulate on the second bottom part BP2 between the comparative wheels WHL′ and the sidewalls SWP.

As shown in FIGS. 15 and 16, holes H′, parallel to the second direction DR2 may be defined in the comparative wheels WHL′. In this case, airflow AF-2 smaller than the above-described airflow AF-1 may be generated through the holes H′.

The airflow AF-2 passing through the holes H′ may not have sufficient speed to disperse the particles PTC accumulated on the second bottom part BP2. Therefore, the airflow AF-2 passing through the holes H′ may fail to disperse the particles PTC accumulated on the second bottom part BP2. As a result, the particles PTC accumulated on the second bottom part BP2 may not be removed (See FIG. 18).

In an embodiment of the invention, the wheels WHL include inclined fan blades FB, which may generate a stronger airflow AF-1. Accordingly, the particles PTC accumulated on the second bottom part BP2 may be more easily removed by the stronger airflow AF-1 generated by the fan blades FB.

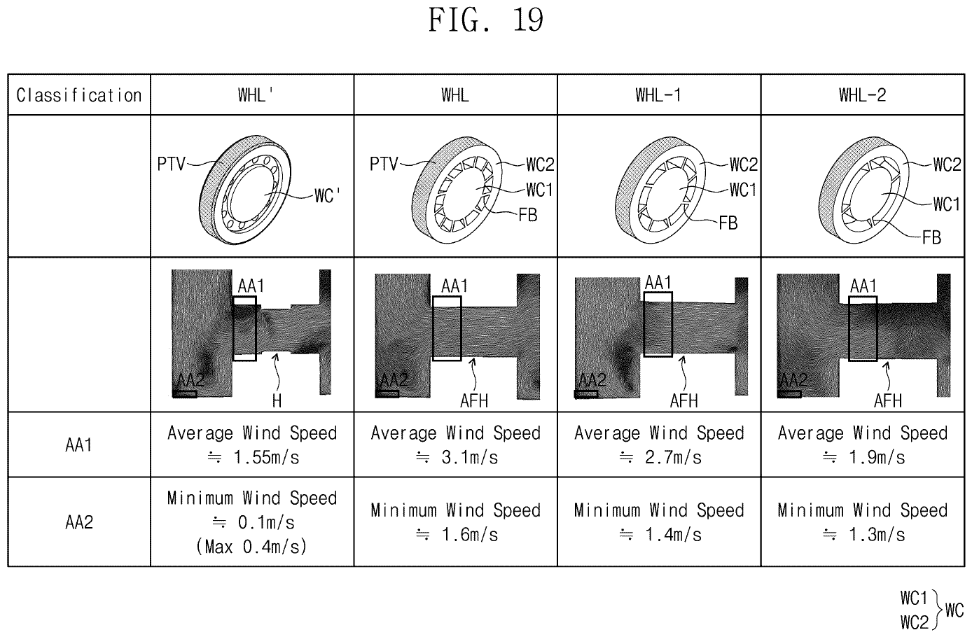

FIG. 19 is a view illustrating simulation results of airflow generated by the wheels according to various embodiments of the invention and by the comparative wheels shown in FIG. 15.

Referring to FIG. 19, the number of fan blades of the wheels WHL, WHL-1, and WHL-2 according to the embodiment of invention may vary. The wheel WHL may have twelve fan blades FB, the wheel WHL-1 may have eight fan blades FB, and the wheel WHL-2 may have four fan blades FB. For example, the airflow holes AFH between the fan blades of the wheels WHL, WHL-1, and WHL-2 are illustrated in a horizontal state.

The average wind speed is a value measured in a first area AA1 of the airflow hole AFH, and the minimum wind speed is a value measured in a second area AA2 on the second bottom part BP2 for the same condition (e.g., the wheels WHL′, WHL, WHL-1, and WHL-2 rotate at the same revolutions per minute (rpm)).

In the comparative wheel WHL′, the average wind speed is measured to be about 1.55 meters per second (m/s), and the minimum wind speed is about 0.1 m/s. In the wheel WHL according to an embodiment, the average wind speed is measured to be about 3.1 m/s, and the minimum wind speed is about 1.6 m/s. In the wheel WHL-1 according to another embodiment, the average wind speed is measured to be about 2.7 m/s, and the minimum wind speed is about 1.4 m/s. In the wheel WHL-2 according to still another embodiment, the average wind speed is measured to be about 1.9 m/s, and the minimum wind speed is about 1.3 m/s.

The minimum wind speed of the wheels WHL, WHL-1, WHL-2 may be higher than that of the comparative wheel WHL′. Therefore, the particles PTC may be more efficiently dispersed by the airflow generated by the wheels WHL, WHL-1, WHL-2. In order to efficiently disperse the particles PTC, a wind speed of at least about 1.4 m/s may be required.

When the comparative wheel WHL′ and the wheels WHL, WHL-1, and WHL-2 are driven, heat may be generated in the comparative wheel core WC′ and the wheel cores WC. Heat may raise the temperature of the protective layer PTV. When the protective layer PTV is heated, the lifespan of the protective layer PTV may decrease.

The airflow may cool the metal, and the greater the airflow, the more the metal may be cooled. As described above, the wind speed by the wheels WHL, WHL-1, and WHL-2 may be higher than that by the comparative wheel WHL′. In this case, the wheel cores WC of the wheels WHL, WHL-1, and WHL-2 may be further cooled than the comparative wheel core WC′ of the comparative wheel WHL′.

Therefore, the protective layer PTV disposed on the wheels WHL, WHL-1, and WHL-2 may be heated less than the protective layer PTV disposed on the comparative wheel WHL′. As a result, the lifespan of the protective layer PTV disposed on the wheels WHL, WHL-1, and WHL-2 may be longer than the protective layer PTV disposed on the comparative wheel WHL′.

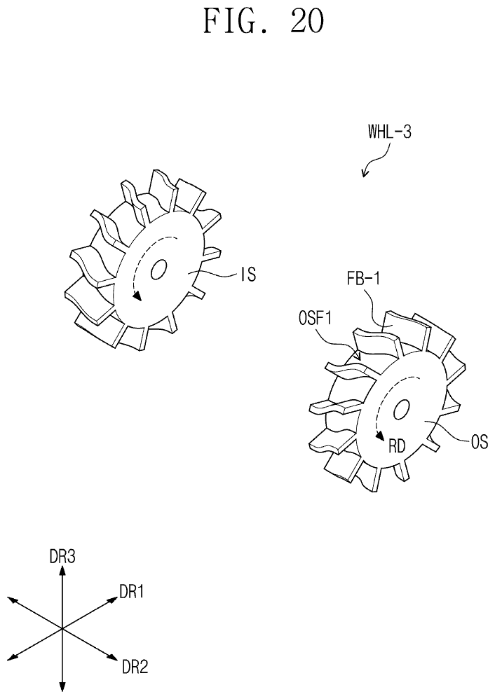

FIG. 20 is a view illustrating a configuration of fan blades according to another embodiment of invention.

For example, FIG. 20 is a perspective view corresponding to the configurations in FIG. 12.

Referring to FIG. 20, in another embodiment of the invention, each fan blade FB-1 of wheels WHL-3 may have a wave shape, unlike the fan blades FB shown in FIG. 12.

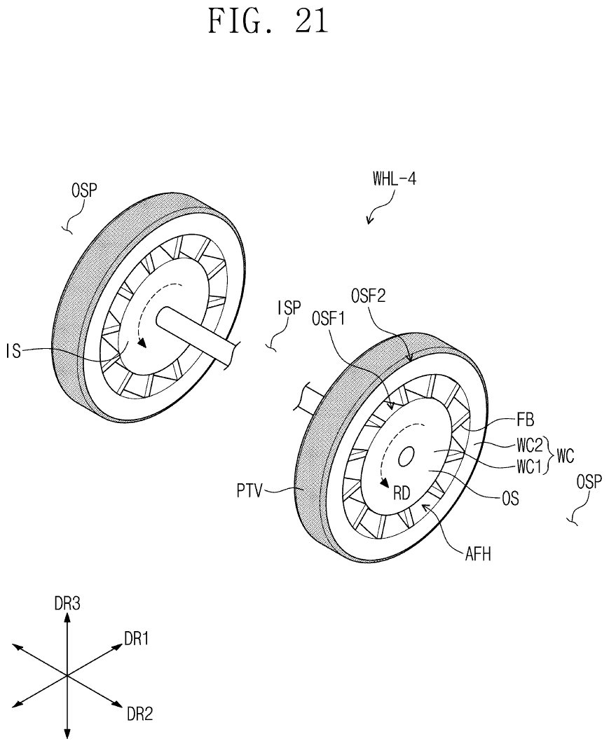

FIG. 21 is a view illustrating a configuration of wheels according to another embodiment of the invention.

For example, FIG. 21 is a perspective view corresponding to the configurations in FIG. 11.

Referring to FIG. 21, fan blades FB of wheels WHL-4 may be manufactured separately from first and second wheel cores WC1 and WC2 and may be connected to the first and second wheel cores WC1 and WC2. For example, the fan blades FB may be connected to the first and second wheel cores WC1 and WC2 by welding. However, it is not limited thereto, and the fan blades FB may also be connected to the first and second wheel cores WC1 and WC2 by fastening units such as screws.

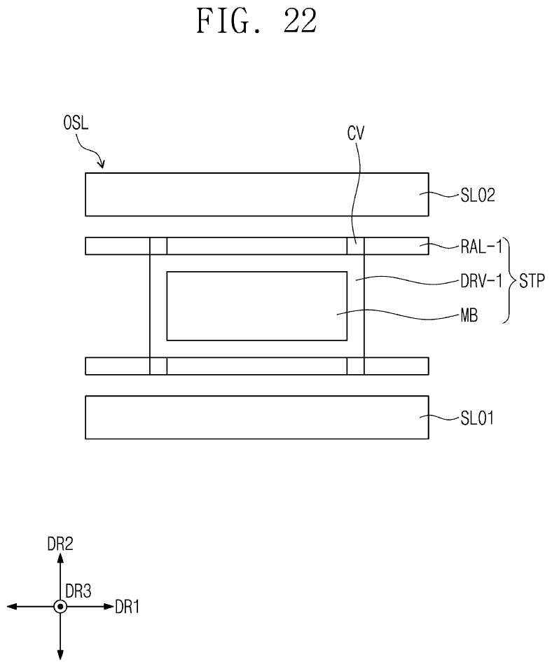

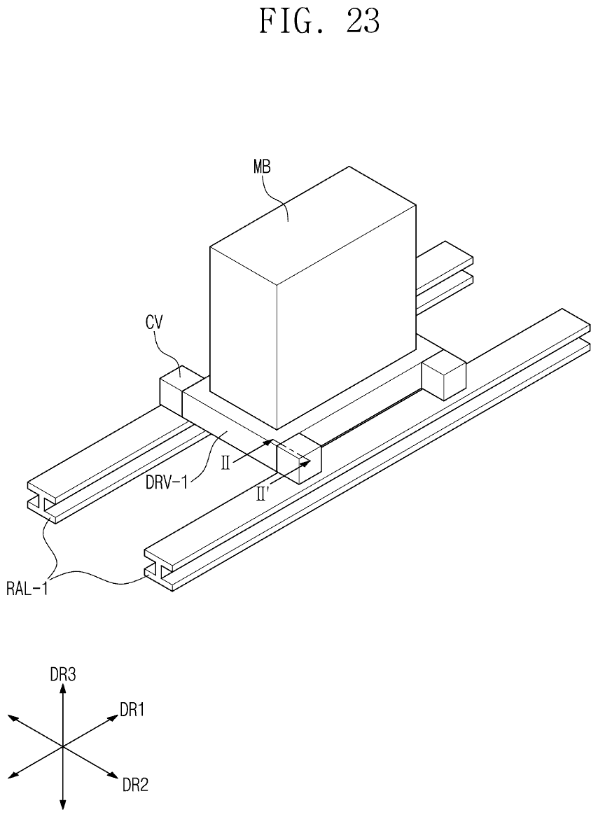

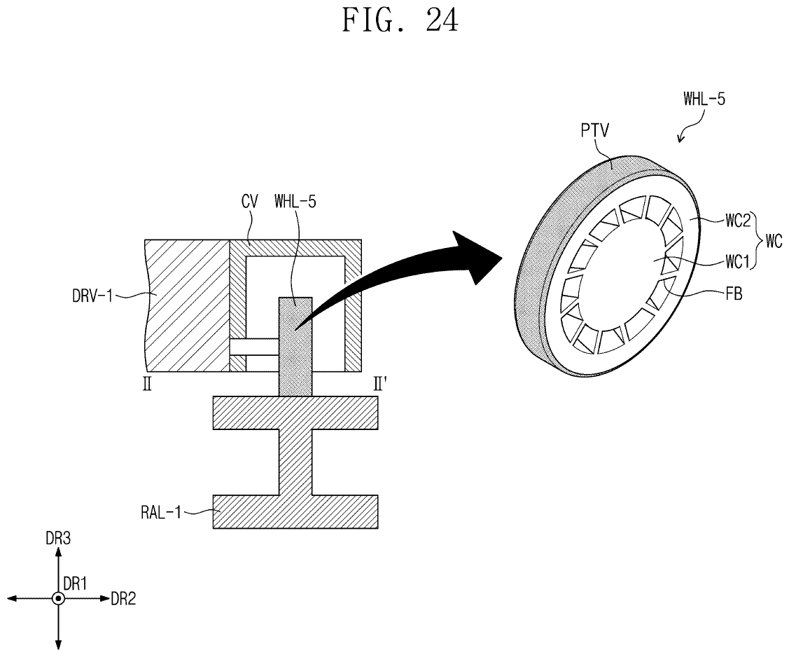

FIG. 22 is a view illustrating a configuration of one of outer substrate loading parts shown in FIG. 1. FIG. 23 is a perspective view of a substrate transfer part shown in FIG. 22. FIG. 24 is a cross-sectional view taken along line II-II′ of FIG. 23.

For example, an outer substrate loading part OSL shown in FIG. 22 may be one of the outer substrate loading parts OSL adjacent to the long side of the booth BOT shown in FIG. 1.

Referring to FIGS. 22, 23, and 24, the outer substrate loading part OSL may include a first substrate loading part SLO1, a second substrate loading part SLO2, and a substrate transfer part STP. The first substrate loading part SLO1 and the second substrate loading part SLO2 may be spaced apart in the second direction DR2. The substrate transfer part STP may be disposed between the first substrate loading part SLO1 and the second substrate loading part SLO2.

The first substrate loading part SLO1 and the second substrate loading part SLO2 may substantially have a configuration similar to the above-described inner substrate loading part CST. The above-described mother substrates M-SUB may be temporarily stored in the first substrate loading part SLO1 and the second substrate loading part SLO2.

The substrate transfer part STP may include a pair of rails RAL-1, a driving part DRV-1, a main body MB, a plurality of wheel covers CV, and a plurality of wheels WHL-5. The rails RAL-1 may extend parallel in the first direction DR1. In a plane view, the driving part DRV-1 may be disposed between the rails RAL-1.

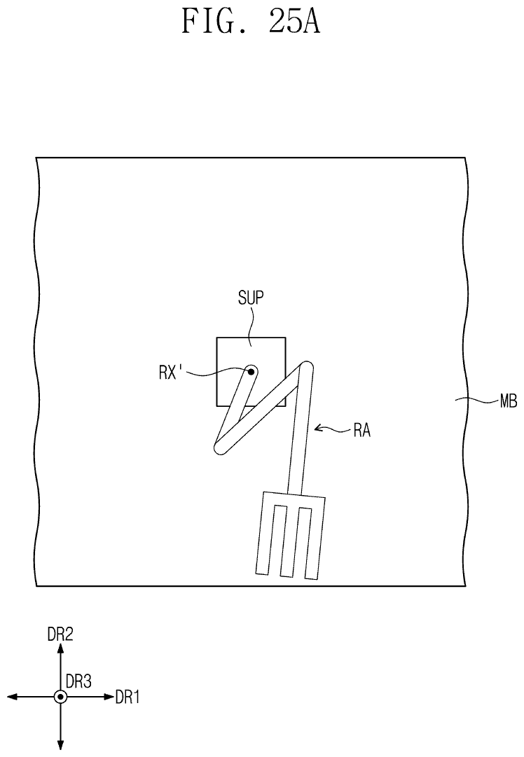

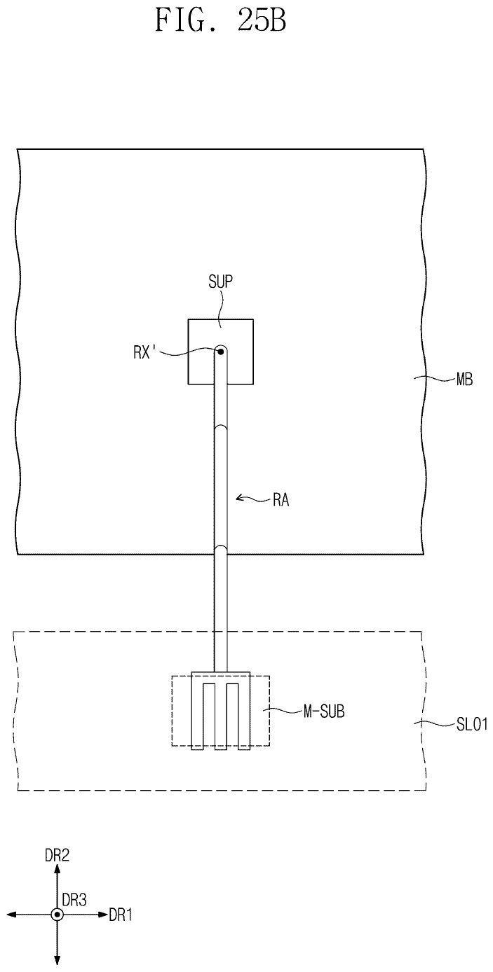

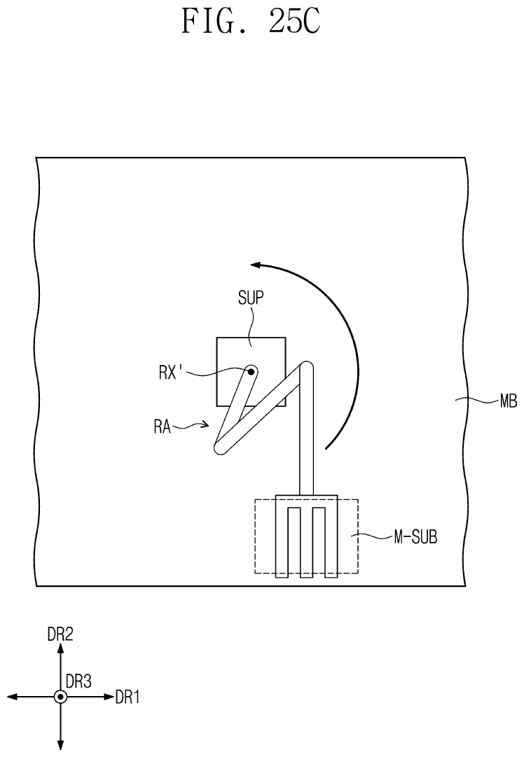

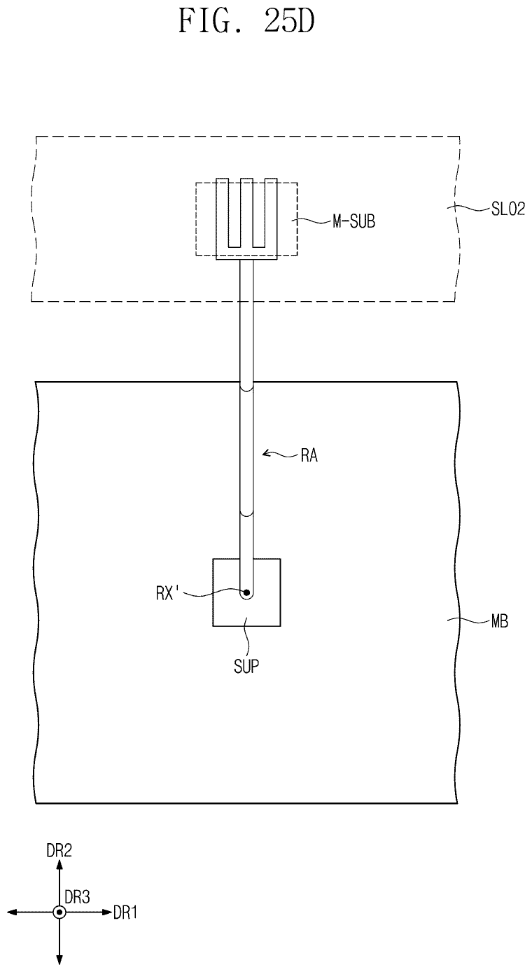

Robot arms RA may be disposed within the main body MB. The configurations of the robot arms will be shown in FIGS. 25A to 25D below.

The driving part DRV-1, the wheel covers CV, and the wheels WHL-5 may be disposed below the main body MB. The wheel covers CV and wheels WHL-5 may be connected to both sides of the driving part DRV-1, which are opposite each other in the second direction DR2. The wheel covers CV and wheels WHL-5 may be disposed on the rails RAL-1.

The wheels WHL-5 may be disposed to be in contact with a top surface of each of the rails RAL-1. The wheel covers CV may be disposed on the wheels WHL-5, respectively to cover the wheels WHL-5. The wheels WHL-5 may be defined as “outer wheels”.

The driving part DRV-1 may transmit driving force to the wheels WHL-5 to rotate the wheels WHL-5. The wheels WHL-5 may rotate around rotation axes parallel to the second direction DR2. The wheels WHL-5 may rotate and move along the rails RAL-1. Therefore, when the wheels WHL-5 rotate, the driving part DRV-1 and the main body MB may move along the rails RAL-1.

In the embodiment of the invention, as shown in FIG. 24, the wheels WHL-5 may have the same configuration as the above-described wheels WHL. The wheels WHL-5 may rotate in the clockwise or counterclockwise direction around the second direction DR2. Therefore, the driving part DRV-1 and the main body MB may reciprocate along the rails RAL-1 in the first direction DR1.

Since the wheels WHL-5 have the same configuration as the wheels WHL, when the wheels WHL-5 move in a leftward direction, which is one direction of the first direction DR1, airflow may be generated toward the outer side of the wheels WHL-5. Therefore, in the substrate transfer part STP, particles generated by the friction between the wheels WHL-5 and the rails RAL-1 may be dispersed by the airflow generated by the wheels WHL-5.

FIGS. 25A to 25D are views illustrating the operation of one of robot arms disposed within the main body shown in FIGS. 22 and 23.

Referring to FIG. 24A, the substrate transfer part STP may include a support part SUP disposed within the main body MB and a robot arm RA connected to the support part SUP, which is also disposed within the main body MB. For example, a robot arm RA disposed within the main body MB is illustrated in FIGS. 24A to 24D; however, substantially, a plurality of robot arms may be disposed within the main body MB.

The robot arm RA may have a folding structure that allows itself to expand and retract in the second direction DR2. Additionally, the robot arm RA may be coupled to the support part SUP so as to rotate. For example, the robot arm RA may rotate around a rotation axis RX′ defined in the support part SUP, and the rotation axis RX′ may be defined parallel to the third direction DR3.

When the robot arm RA expands in the second direction DR2, the robot arm RA may extend outward from the main body MB. In FIGS. 22 and 23, the main body MB is illustrated in a simplified box shape; however, the main body MB may substantially be opened in the second direction DR2 to accommodate the movement of the robot arm RA.

Referring to FIGS. 22 and 24B, the robot arm RA may expand in the second direction DR2 and extend toward the first substrate loading part SLO1, and one of the mother substrates M-SUB disposed on the robotic arm RA. As an example, in FIG. 24B, the first substrate loading part SLO1 is illustrated with dotted lines.

Referring to FIGS. 22 and 24C, the robot arm RA may retract in the second direction DR2, allowing the mother substrate M-SUB to be disposed within the main body MB.

Referring to FIGS. 22, 24C, and 24D, the robot arm RA may rotate about the rotation axis RX′ and then expand in the second direction DR2 toward the second substrate loading part SLO2. The mother substrate M-SUB disposed on the robot arm RA may be loaded onto the second substrate loading part SLO2. As an example, in FIG. 24D, the second substrate loading part SLO2 is illustrated with dotted lines.

Although not illustrated, additional robot arms may be disposed between the first substrate loading part SLO1 and the booth BOT, as well as between the second substrate loading part SLO2 and the chamber CH. By the additional robot arms, the mother substrate M-SUB may be transferred from the vehicle VHC to the first substrate loading part SLO1 or from the first substrate loading part SLO1 to the vehicle VHC. Furthermore, the additional robot arms may transfer the mother substrate M-SUB from the second substrate loading part SLO2 to the chamber CH or from the chamber CH to the second substrate loading part SLO2.

The substrate transfer part STP may reciprocate in the first direction DR1 and move to the positions of the first and second substrate loading parts SLO1 and SLO2, in which the mother substrate M-SUB to be transferred is disposed. By the rotation of the above-described wheels WHL-5, the main body MB may move along the rails RAL-1 in the first direction DR1, enabling the robot arm RA to move to the position in which the mother substrate M-SUB to be transferred is disposed.

According to an embodiment of the invention, the wheels of the vehicle in the substrate transfer apparatus may generate an airflow directed from the inside to the outside, thereby dispersing contamination particles accumulated between the wheels and the rails and allowing the contamination particles to be easily removed.

Although the embodiments of the present disclosure have been described, it is understood that various changes and modifications can be made by one ordinary skilled in the art within the spirit and scope of the present disclosure as hereinafter claimed. Also, the embodiments disclosed in the present disclosure are not intended to limit the technical idea of the present disclosure, and all technical ideas within the following claims and their equivalents should be interpreted as being included in the scope of the present disclosure.

What is claimed is:

1. An apparatus for transferring a substrate, the apparatus comprising:
a loading plate;
an inner substrate loading part disposed on the loading plate;
a rail disposed below the loading plate and extending in a first direction;
a driving part disposed in an accommodation space defined within the rail, and connected to the loading plate through an opening defined in an upper portion of the rail; and
a plurality of inner wheels connected to both opposing sides of the driving part in a second direction that intersects perpendicular to the first direction,
wherein each of the inner wheels comprises:
a first wheel core;
a second wheel core surrounding a first outer circumferential surface of the first wheel core when viewed in the second direction; and
a plurality of fan blades disposed between the first wheel core and the second wheel core,
wherein, when viewed in the first direction, the fan blades are disposed to be inclined at a first angle with respect to the second direction.

2. The apparatus of claim 1, wherein each of the fan blades has a flat plate shape.

3. The apparatus of claim 1, wherein each of the inner wheels comprises an inner surface facing the driving part and an outer surface opposite to the inner side surface, and
each of the fan blades comprises a first side adjacent to the inner surface of each of the inner wheels and a second side adjacent to the outer surface of each of the inner wheels,
wherein, when viewed in the first direction, a reference line extending from the second side of each of the fan blades in the second direction to overlap the first outer circumferential surface of the first wheel core is defined, and
each of the fan blades is disposed to be inclined at an acute angle with respect to the reference line.

4. The apparatus of claim 3, wherein, when viewed in the first direction, the first side of each of the fan blades and the second side of each of the fan blades are disposed at different heights.

5. The apparatus of claim 3, wherein the inner wheels are configured to rotate in a same direction around a rotation axis parallel to the second direction, and
when viewed from the first direction, which is a traveling direction of the loading plate, the first side of each of the fan blades is disposed lower than the second side of each of the fan blades.

6. The apparatus of claim 3, wherein, when the inner wheels rotate, an airflow is generated from an inner space between the inner wheels toward an outer space of the inner wheels, which is opposite to the inner space, through a plurality of airflow holes defined between the fan blades.

7. The apparatus of claim 6, wherein the rail comprises:
a sidewall facing the outer surface of each of the inner wheels; and
a bottom part disposed below the inner wheels,
wherein a minimum velocity of the airflow on a portion of the bottom part disposed between the outer surface of each of the inner wheels and the sidewall is about 1.4 meters per second (m/s).

8. The apparatus of claim 5, wherein, when viewed in the second direction, each of the fan blades is disposed to be inclined at a second angle with respect to a normal line extending in a direction perpendicular to the rotation axis and crossing a contact portion between the second side and the outer surface.

9. The apparatus of claim 8, wherein the second angle is an acute angle.

10. The apparatus of claim 8, wherein each of the fan blades is disposed to be inclined in a rotational direction of the inner wheels relative to the normal line.

11. The apparatus of claim 1, wherein, when viewed in the second direction, each of the inner wheels further comprises a protective layer surrounding a second outer circumferential surface of the second wheel core, the protective layer having predetermined elasticity.

12. The apparatus of claim 1, wherein a total number of fan blades in each inner wheel are 4n in number, where n is a natural number.

13. The apparatus of claim 1, further comprising a blower disposed on the loading plate and configured to provide an airflow toward the rail.

14. The apparatus of claim 13, wherein the rail comprises a bottom part disposed below the driving part, and
a plurality of holes through which the airflow is discharged are defined in the bottom part.

15. The apparatus of claim 1, wherein the fan blades are integrally provided with the first and second cores.

16. The apparatus of claim 1, wherein each of the fan blades has a wave shape.

17. The apparatus of claim 1, wherein the fan blades are separately manufactured from the first and second cores and are connected to the first and second cores.

18. The apparatus of claim 1, further comprising:
a first substrate loading part configured to receive a substrate loaded onto the inner substrate loading part;
a second substrate loading part spaced apart from the first substrate loading part in the second direction; and
a substrate transfer part disposed between the first and second substrate loading parts,
wherein the substrate transfer part comprises:
a main body;
a robot arm disposed within the main body and expandable toward the first and second substrate loading parts; and
a plurality of outer wheels disposed below the main body,
wherein the outer wheels have a same configuration as the inner wheels.

19. An apparatus for transferring a substrate, the apparatus comprising:
a loading plate;
a substrate loading part disposed on the loading plate;
a driving part disposed below the loading plate; and
a plurality of wheels connected to both opposing sides of the driving part in a first direction,
wherein each of the wheels comprises:
a first wheel core;
a second wheel core surrounding an outer circumferential surface of the first wheel core; and
a plurality of fan blades disposed between the first wheel core and the second wheel core,
wherein each of the wheels comprises an inner surface facing the driving part and an outer surface opposite to the inner side surface,
each of the fan blades comprises a first side adjacent to the inner surface of each of the wheel and a second side adjacent to the outer surface of each of the wheel, and
the first side of the fan blade and the second side of the fan blade are disposed at different heights when viewed in a second direction perpendicular to the first direction.

20. An apparatus for transferring a substrate, the apparatus comprising:
a loading plate;
a substrate loading part disposed on the loading plate;
a driving part disposed below the loading plate; and
a plurality of wheels connected to both opposing sides of the driving part in a certain direction,
wherein each of the wheels comprises:
a first wheel core;
a second wheel core surrounding an outer circumferential surface of the first wheel core; and
a plurality of fan blades disposed between the first wheel core and the second wheel core,
wherein each of the wheels comprises an inner surface facing the driving part and an outer surface opposite to the inner side surface, and
each of the fan blades comprises a first side adjacent to the inner surface of each of the wheels and a second side adjacent to the outer surface of each of the wheels, and
wherein a reference line extending from the second side of each of the fan blades in the certain direction is defined, and
each of the fan blades is disposed to be inclined at an acute angle with respect to the reference line.
